(19) United States
(12) Patent Application Publication
(10) Pub. No.: US 2025/0007470 A1
(43) Pub. Date: Jan. 2, 2025

(54) POWER AMPLIFIER

(71) Applicants: Ampleon Netherlands B.V., Nijmegen (NL); Ampleon Semiconductors (Shanghai) Co. Ltd, Shanghai (CN)

(72) Inventors: Xiaochuan Jiang, Nijmegen (NL); Yan Xia, Nijmegen (NL); Binghui Zhang, Nijmegen (NL)

(21) Appl. No.: 18/710,377

(22) PCT Filed: Nov. 15, 2022
(86) PCT No.: PCT/CN2022/132075

§ 371 Date: May 15, 2024

(30) Foreign Application Priority Data
Nov. 15, 2021 (CN) 202111350252.3

(51) Int. Cl. H03F 1/56; H03F 3/24

(52) U.S. Cl. CPC H03F 1/56; H03F 3/24; H03F 2200/387; H03F 2200/451

(57) ABSTRACT

The present invention relates to a power amplifier. The present invention particularly relates to switched-mode power amplifiers operable in a frequency range between 0.5 GHz and 40 GHz, and configured for outputting powers ranging from 1 W to 1 kW. The present invention further relates to an impedance matching stage to be used in such power amplifier. The impedance matching stage of the present invention comprises a short-circuited stub at its input, an open-circuited stub at its output, and a series branch connecting the input and output. By choosing suitable characteristic impedances and electrical lengths of the stubs and the series branch it becomes possible to independently choose the impedance to be presented to the power transistor at the fundamental and second harmonic frequencies.

The present invention relates to a power amplifier. The present invention particularly relates to radiofrequency, RF, power amplifiers, and more in particular to switched-mode power amplifiers operable in a frequency range between 0.5 GHz and 40 GHz and configured for outputting powers ranging from 1 W to 1 kW. The present invention further relates to an impedance matching stage used in such power amplifier.

Power amplifiers are known in the art. For example, power amplifiers are used for amplifying telecommunication signals in base stations. Typically, these power amplifiers comprise silicon-based laterally diffused metal-oxide-semiconductor, LDMOS, transistors, or gallium nitride-based field-effect transistors, FETs.

To obtain suitable power added efficiency and gain values, it is important to provide proper impedances at the output of the transistor, not only at the fundamental frequency but also at the second and higher harmonic frequencies. Such impedances are typically provided using impedance matching stages that transform an impedance value of a load connected to the power amplifier to a suitable impedance value to be provided to the power transistor of the power amplifier.

Providing suitable impedance levels at harmonic frequencies is particularly important when the power amplifier is a switched-mode power amplifier in which harmonic impedances are responsible for generating the desired voltage and/or current waveforms for example to allow zero voltage switching.

A common problem with designing power amplifiers of the type described above is that impedances at the fundamental frequency and the second and higher harmonic frequencies are generally correlated. As a result, when optimizing impedance matching stages for a given impedance at the fundamental frequency, impedance levels at the second and higher harmonic frequencies are affected as well. It is therefore complicated to design an impedance matching stage for a given impedance at the fundamental frequency and a given impedance at a harmonic frequency at the same time. This problem is particularly relevant for impedances at the second harmonic frequency.

It is an object of the present invention to provide an impedance matching stage in which the abovementioned problem does not occur or at least to a lesser extent.

According to the present invention, this object is achieved using the impedance matching stage as defined in appended claim 1 that comprises an input and an output, a short-circuited stub connected to the input, an open-circuited stub connected to the output, and a series branch arranged in between the input and output.

According to the present invention, the open-circuited stub and the series branch are configured to set an input impedance of the impedance matching stage at a fundamental frequency in dependence of a load impedance when this impedance is connected to the output. The short-circuited stub is configured to set the input impedance of the impedance matching stage at a second harmonic frequency.

Within the context of the present invention, the wording fundamental frequency and second harmonic frequency may correspond to 1 or 2 times the operational frequency of the power amplifier or other electronic component the impedance matching stage is connected to. This operational frequency typically lies within a given range, e.g. between 0.5 GHz and 40 GHz. For power amplifiers for telecommunications, the operational frequency may correspond to the frequency of the carrier.

The open-circuited stub and the series branch can be configured to transform the load impedance when connected to the output to a first desired impedance at the fundamental frequency while not or at most marginally affecting the input impedance of the impedance matching stage at the second harmonic frequency. Additionally, the short-circuited stub can be configured to have an input impedance at the second harmonic frequency that substantially equals a second desired impedance while not or at most marginally affecting the input impedance of the impedance matching stage at the fundamental frequency.

It is noted that the first desired input impedance and the second desired impedance are typically determined by the power transistor or other electronic component that is connected to the input of the impedance matching stage. The configuration of the components of the impedance matching stage generally depends on these impedances as well as the load impedance of the load that is connected to the output of the impedance matching stage.

The open-circuited stub and series branch can be configured to substantially transform, at the fundamental frequency, the load impedance when connected to the output to the first desired impedance at the input, and to present an impedance at the input at the second harmonic frequency that is substantially greater than the second desired impedance. Furthermore, an input impedance of the short-circuited stub at the fundamental frequency can be substantially greater than the first desired impedance, and an input impedance of the short-circuited stub at the second harmonic frequency may substantially equal the second desired impedance.

According to the present invention, the series branch and open-circuited stub ensure a proper input impedance of the impedance matching stage at the fundamental frequency. At the same time, an impedance seen looking into the series branch at the second harmonic frequency will not be infinite. However, as long as this impedance is considerably greater than the input impedance of the short-circuited stub, it is possible to independently design for providing a suitable impedance at the fundamental and second harmonic frequency.

A voltage standing wave ratio R1 associated with an impedance at the fundamental frequency at the input looking into the series branch and referenced to the first desired impedance may be less than 1.3. Put differently, R1 is chosen different from 1 to compensate the effect the short-circuited stub has at the input impedance at the fundamental frequency.

Similarly, a voltage standing wave ratio R2 associated with an input impedance of the short-circuited stub at the second harmonic frequency referenced to the second desired impedance can be less than 2.

The open-circuited stub may comprise a first transmission line having a first characteristic impedance and a first electrical length, wherein the first electrical length corresponds to 45 degrees at or near the fundamental frequency. In addition, the series branch may comprise a second transmission line having a second characteristic impedance and a second electrical length, wherein the second electrical length corresponds to 45 degrees at or near the fundamental frequency. Because the first electrical length will be 90 degrees at or near the second harmonic frequency, the open-circuited stub will function as a quarter-wave transmission line and the input impedance of the open-circuited stub will be close to zero Ohm. Consequently, the impedance at the second harmonic frequency seen by the series branch, which corresponds to the parallel connection of the open-circuited stub and the connected load, will also be close to zero Ohm. At the same time, at the second harmonic frequency, the series branch, which then also acts as a quarter-wave transmission line, transforms the low value for the impedance at the second harmonic frequency to a very high value at the input of the impedance matching stage.

At the fundamental frequency, both the open-circuited stub and the series branch affect the impedance seen at the input of the impedance matching stage. As a theoretical example, the impedance seen at the input of a lossless transmission line with characteristic impedance Z0 and length θ, and that is terminated with an impedance Z, can be found using:

$$Zin = Z 0 ( \frac{Z + jZ 0 tan θ}{Z 0 + jZ tan θ} ) \qquad EQ1$$

For the open-circuited stub, for which Z=∞, and which has a characteristic impedance Z1 and electrical length θ₁=π/4 at the fundamental frequency, the input impedance can be computed using:

$$Zin = Z 1 ( \frac{Z}{jZ tan {θ}_{1}} ) = - jZ 1 \qquad EQ . 2$$

This impedance is parallel to the load impedance ZL, which is assumed to have a real value. Consequently, the impedance Zin2 at the input of the impedance matching stage can be computed using:

$$Zin 2 = Z 2 ( \frac{Zp + j Z 2 tan {θ}_{2}}{Z 2 + j Zp tan {θ}_{2}} ) = Z 2 ( \frac{Zp + jZ 2}{Z 2 + jZp} ) \qquad EQ . 3$$

$$with$$

$$Zp = \frac{Z L Z {1}^{2} - jZ 1 {ZL}^{2}}{Z {1}^{2} + Z {L}^{2}} \qquad EQ . 4$$

The impedance Zin2 at the input of the impedance matching stage should match a first desired impedance Zdes1, which typically corresponds to the optimal impedance to be presented at the output of a power transistor for achieving maximum gain and/or efficiency. This requirement results in two equations, one for the real part and one for the imaginary part. For a given value of ZL and Zdes1, a unique solution can therefore be found for Z1 and Z2, which characteristic impedances are typically different from each other.

In practice, transmission lines are never truly lossless. In addition, the electrical length may slightly deviate from 45 degrees at the fundamental frequency. However, in general, the first characteristic impedance and second characteristic impedance are preferably such that, for a given load impedance connected at the output, the impedance looking into the series branch from the input substantially equals the first desired impedance at the fundamental frequency.

The short-circuited stub may comprise a third transmission line arranged in series with a shorted fourth transmission line. The third transmission line may have a third characteristic impedance and a third electrical length, and the fourth transmission line may have a fourth characteristic impedance and a fourth electrical length. Using two transmission lines, provides four degrees of freedom (2× characteristic impedance and 2× electrical length) for simultaneously obtaining the goal of not affecting the input impedance of the impedance matching stage at the fundamental frequency, at least not to a significant degree, while at the same time setting the input impedance of the impedance matching stage at the second harmonic frequency, or at least to a large extent.

The Applicant has found that suitable solutions can still be found when keeping a sum of the third electrical length and fourth electrical length equal to 90 degrees at or near the fundamental frequency. In this case, the third characteristic impedance and fourth characteristic impedance are preferably different. The third characteristic impedance and fourth characteristic impedance are preferably such that the impedance at the second harmonic frequency at the input looking into the short-circuited stub equals the second desired impedance.

With the fourth transmission line having characteristic impedance Z4 and electrical length θ₄ being short-circuited, the impedance seen looking into the fourth transmission line equals:

$$Zin 4 = Z 4 ( \frac{0 + j Z 4 tan {θ}_{4}}{Z 4 + j 0 tan {θ}_{4}} ) = Z 4 ( \frac{j Z 4 tan {θ}_{4}}{Z 4} ) = j Z 4 tan {θ}_{4} \qquad EQ . 5$$

whereas the impedance looking into the third transmission line having characteristic impedance Z3 and electrical length θ₃ equals:

$$Zin 3 = Z 3 ( \frac{j Z 4 tan {θ}_{4} + j Z 3 tan {θ}_{3}}{Z 3 - Z 4 tan {θ}_{4} tan {θ}_{3}} ) \qquad EQ . 6$$

At the fundamental frequency:

$${θ}_{3} + {θ}_{4} = π / 2 \qquad EQ . 7$$

$$tan {θ}_{4} = tan ( \frac{π}{2} - {θ}_{3} ) = cot {θ}_{3} \qquad EQ . 8$$

Combining this with EQ. 6, yields:

$$Zin 3 = Z 3 ( \frac{jZ 4 cot {θ}_{3} + jZ 3 tan {θ}_{3}}{Z 3 - Z 4 cot {θ}_{3} tan {θ}_{3}} ) = Z 3 ( \frac{jZ 4 cot {θ}_{3} + jZ 3 tan {θ}_{3}}{Z 3 - Z 4} ) \qquad EQ . 9$$

When Z3=Z4 this yields the familiar result that Zin3=j∞ and the impedance at the fundamental frequency is not affected. At the same time, when Z3 and Z4 are different, the impedance at the second harmonic frequency seen at the node between the short-circuited stub and the second transmission line can be tuned. More in particular, at the second harmonic frequency:

$${θ}_{3} + {θ}_{4} = π \qquad EQ . 10$$

$$giving$$

$$tan {θ}_{3} = tan ( π - {θ}_{4} ) = - tan ( {θ}_{4} ) \qquad EQ . 11$$

Combining this with equation 6, yields:

$$Zin 3 = Z 3 ( \frac{- j Z 4 tan {θ}_{3} + j Z 3 tan {θ}_{3}}{Z 3 - Z 4 {( tan {θ}_{3} )}^{2}} ) = - jZ 3 tan {θ}_{3} ( \frac{Z 4 - Z 3}{Z 3 - Z 4 {( tan {θ}_{3} )}^{2}} ) \qquad EQ . 12$$

When Z3=Z4 this yields the familiar result Zin3=0 at the second harmonic frequency. Furthermore, the short-circuited stub typically acts as a single quarter-wavelength transmission at the fundamental frequency that transforms the short to an open thereby not affecting the input impedance of the impedance matching stage at the fundamental frequency.

Depending on the values for Z3, Z4, and θ₃, a desired impedance at the second harmonic frequency other than 0 can be realized at the expense of a minor impact on the impedance at the fundamental frequency. In general, a greater range of values of the impedance at the second harmonic frequency can be realized for greater differences between the third and fourth transmission lines, both in characteristic impedance and effective length.

The Applicant has found that a greater range of values for the impedance at the second harmonic frequency can be obtained when the ratio between Z3 and Z4 deviates more from one. The ratio R3 between the third characteristic impedance and fourth characteristic impedance preferably lies in a range between 0.2<=R3<=5. This range offers an acceptable trade-off between the range of possible impedances at the second harmonic frequency and the impact the short-circuited stub has on the input impedance of the impedance matching stage at the fundamental frequency. In general, the third characteristic impedance and fourth characteristic impedance are such that the impedance at the second harmonic frequency at the input looking into the short-circuited stub equals the second desired impedance.

Assuming that Zin2 is a real number, that Z3=mZin2, and that Z4=nZ3, EQ. 9 reduces to:

$$Zin 3 = mZin 2 ( \frac{jnmZin 2 cot {θ}_{3} + jmZin 2 tan {θ}_{3}}{mZin 2 - nmZin 2} ) = jmZin 2 ( \frac{n + {( tan {θ}_{3} )}^{2}}{( 1 - n ) tan {θ}_{3}} ) \qquad EQ . 13$$

The impedance Zin seen looking into the input of the impedance matching stage corresponds to the parallel combination of Zin3 and Zin2 and corresponds, at the fundamental frequency, to:

$$Zin = \frac{Zin 2}{1 + \frac{Zin 2 n 2}{Zin 3}} = \frac{Zin 2}{1 + \frac{Zin 2 ( 1 - n ) tan {θ}_{3}}{jmZin 2 ( n + {( tan {θ}_{3} )}^{2} )}} = \frac{Zin 2}{1 - \frac{j ( 1 - n ) tan {θ}_{3}}{m ( n + {( tan {θ}_{3} )}^{2} )}} \qquad EQ . 14$$

which can be written in the following form:

$$Zin = \frac{Zin 2}{1 - \frac{j ( 1 - n ) tan {θ}_{3}}{m ( n + {( tan {θ}_{3} )}^{2} )}} = \frac{Zin 2}{1 - j α / β} \qquad EQ . 15$$

$$α / β = \frac{( 1 - n ) tan {θ}_{3}}{m ( n + {( tan {θ}_{3} )}^{2} )} \qquad EQ . 16$$

The reflection coefficient referenced to Zin2 can be computed using:

$$REFL = \frac{Z in - Zin 2}{Z in + Zin 2} = \frac{Zin 2 - Zin 2 ( 1 - j α / β )}{Zin 2 + Zin 2 ( 1 - j α / β )} = \frac{j α / β}{2 - j α / β} = \frac{j α}{2 β - j α} \qquad EQ . 17$$

Using EQ. 16, the voltage standing wave ratio, VSWR, at the fundamental frequency can be computed using:

$$V S W R = \frac{1 + \vert REFL \vert}{1 - \vert REFL \vert} = \frac{1 + \vert \frac{j ( 1 - n ) tan {θ}_{3}}{2 m ( n + {( tan {θ}_{3} )}^{2} ) - j ( 1 - n ) tan {θ}_{3}} \vert}{1 - \vert \frac{j ( 1 - n ) tan {θ}_{3}}{2 m ( n + {( tan {θ}_{3} )}^{2} ) - j ( 1 - n ) tan {θ}_{3}} \vert} \qquad EQ . 18$$

When n=1, i.e. Z3=Z4, the familiar result VSWR=1 is obtained as the short connected to the fourth transmission line is transformed into an open at the fundamental frequency.

Again, assuming that Zin2 is a real number, that Z3=mZin2, and that Z4=nZ3, EQ. 12 reduces to:

$$Zin 3 = Z 3 ( \frac{- j Z 4 tan {θ}_{3} + j Z 3 tan {θ}_{3}}{Z 3 + Z 4 {( tan {θ}_{3} )}^{2}} ) = jmZin 2 tan {θ}_{3} ( \frac{1 - n}{1 + n {( tan {θ}_{3} )}^{2}} ) \qquad EQ . 19$$

At the second harmonic frequency, Zin2=∞. Next, Zin3 is referenced to the value of Zin2 at the fundamental frequency. More in particular, a phase angle P is defined by looking at the argument of an impedance consisting of Zin3 and Z2in in series:

$$P = {tan}^{- 1} \frac{mZin 2 tan {θ}_{3} ( \frac{1 - n}{1 + n {( tan {θ}_{3} )}^{2}} )}{Zin 2} = {tan}^{- 1} ( \frac{m ( 1 - n ) tan {θ}_{3}}{1 + n {( tan {θ}_{3} )}^{2}} ) \qquad EQ . 20$$

which can take on positive and negative values. A phase angle range can be defined as the difference between the maximum and minimum values of P.

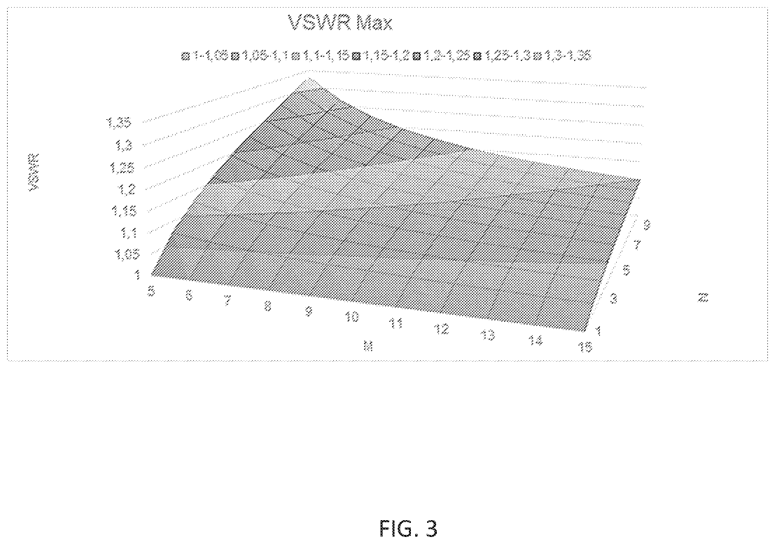

FIG. 3 illustrates the maximum VSWR of EQ. 18 when sweeping θ₃ for given values of m and n.

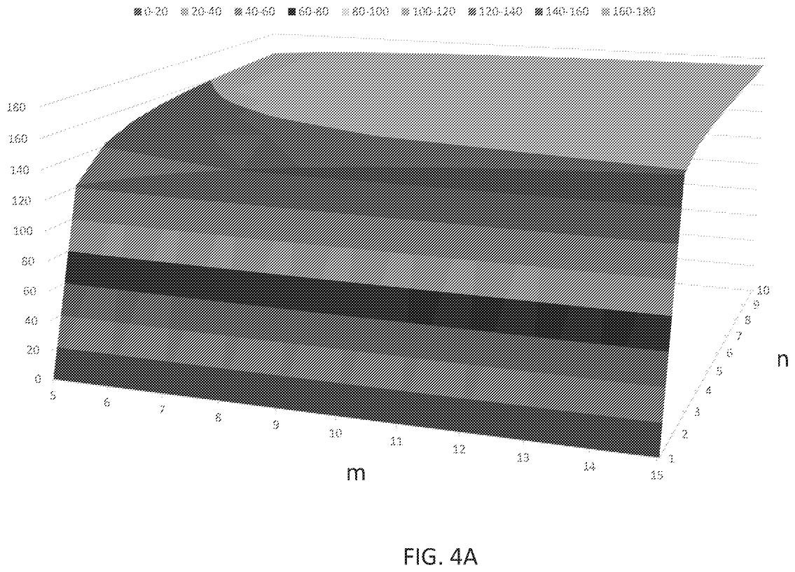

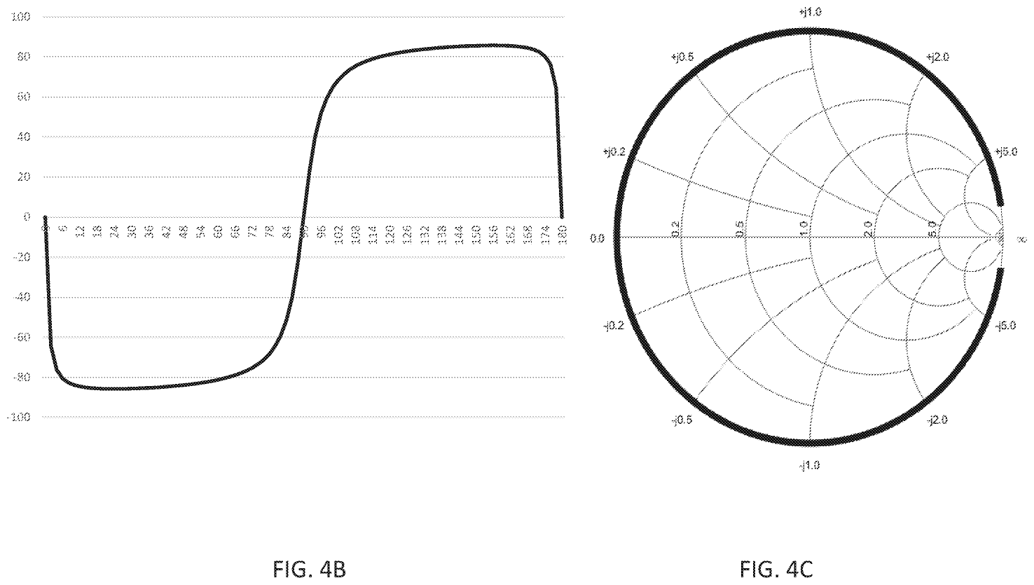

FIG. 4A illustrates the phase angle range as a function of m and n when sweeping θ₃ between 0 and 180 degrees at the second harmonic frequency. When n=1, Z3=Z4, and the combination of the third and fourth transmission lines act as a single transmission line having an electrical length of 180 degrees. Consequently, the range in phase angles is zero in this case. Furthermore, as can be seen in the upper part of the graph, a large phase angle range can be observed if the ratio between n and m deviates strongly from 1.

FIG. 4B illustrates the phase angle range when sweeping θ₃ between 0 and 180 degrees at the second harmonic frequency for m=15 and n=5. Here, it is noted that the maximum phase angle equals zero when θ₃=90 degrees as the third and fourth transmission lines then both act as a quarter wavelength transformer, where the fourth transmission line converts the short into an open, and the third transmission line the open in a short. Furthermore, at θ₃=0, the third transmission line is absent and the fourth transmission line acts as a 180 degrees transmission line that does not perform an impedance transformation. Similarly, at θ₃=0, the fourth transmission line is absent and the third transmission line acts as a 180 degrees transmission line that does not perform an impedance transformation.

FIG. 4C illustrates the position of Zin at the second harmonic frequency, and therefore of Zin3, for values of θ₃ between 0 and 180 degrees and for m=15 and n=5 on a Smith chart that is referenced to the value of Zin2 at the fundamental frequency. As can observed from FIG. 4C in combination with FIG. 3, it is possible to cover a wide range of impedances at the second harmonic frequency without introducing an excessively high VSWR.

The impedance matching stage may comprise a printed circuit board, wherein at least one of the short-circuited stub, the open-circuited stub, and the series branch is realized on or in the printed circuit board.

According to a second aspect, the present invention provides a power amplifier that comprises a main input terminal for receiving a signal to be amplified, a main output terminal for connecting to a load and for outputting the amplified signal to said load, and a power transistor having an input terminal electrically connected to the main input terminal, and an output terminal. The power amplifier according to the second aspect further comprises the impedance matching stage described above of which the input is electrically connected to the output terminal of the power transistor, and of which the output is connected to the main output terminal.

The power amplifier can be a switched-mode power amplifier. For example, the switched-mode power amplifier can be a class-F, class-E, or class-J amplifier. Alternatively, the power amplifier is a Doherty amplifier.

The power amplifier may further comprise a first auxiliary impedance matching network arranged in between the output terminal of the power transistor and the input of the impedance matching stage. In this case, the input impedance of the impedance matching stage, both at the fundamental and second harmonic frequencies, will be transformed by the first auxiliary impedance matching network before reaching the output of the power transistor.

Similarly, the power amplifier may further comprise a second auxiliary impedance matching network arranged in between the output of the impedance matching stage and the main output terminal. In this case, the impedance at the output of the impedance matching stage does not correspond to the impedance of the load at the output of the power amplifier but corresponds to the transformed impedance value.

The power transistor may comprise a silicon-based laterally diffused metal-oxide-semiconductor, LDMOS, transistor, or a gallium nitride-based field-effect transistor, FET. However, other transistor technologies are not excluded.

The power transistor can be provided as a packaged device or bare semiconductor die mounted on the printed circuit board. In such case, the first auxiliary impedance matching stage may at least be partially formed using the electrical connection between the power transistor on the semiconductor die and the printed circuit board. Such connection may for example comprise bondwires.

Next, the present invention will be described in more detail referring to the appended drawings, wherein:

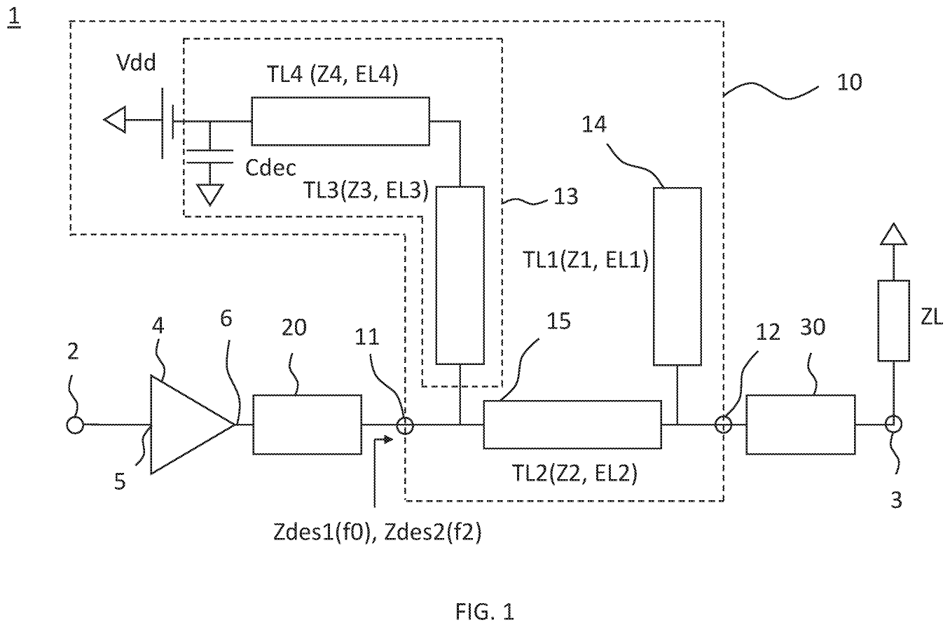

FIG. 1 illustrates an embodiment of a power amplifier in accordance with the present invention;

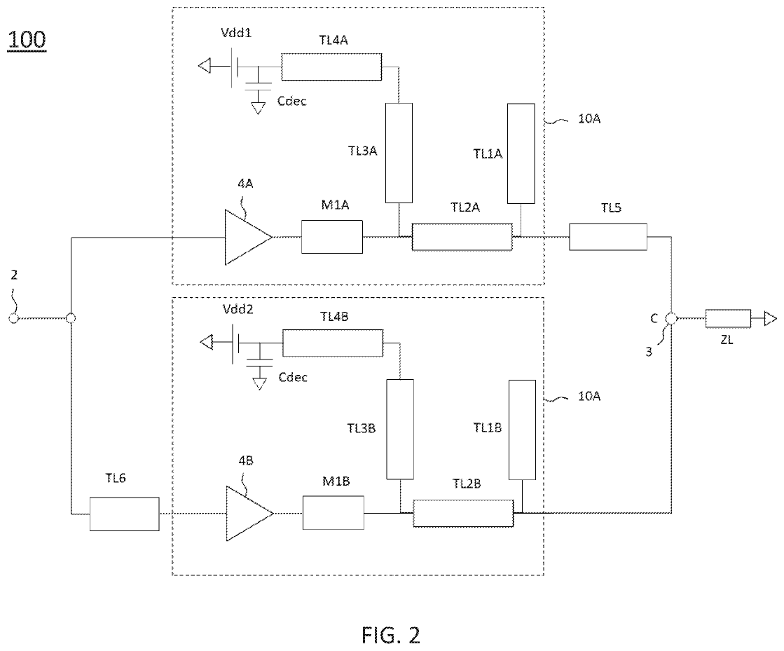

FIG. 2 illustrates a further embodiment of a power amplifier in accordance with the present invention; and

FIG. 3 illustrates the maximum VSWR at the input of the impedance matching stage;

FIG. 4A illustrates the phase angle range associated with the impedance seen looking into the impedance matching stage at the second harmonic frequency for different configurations of the third and fourth transmission lines;

FIG. 4B illustrates the phase angle associated with the impedance seen looking into the impedance matching stage at the second harmonic frequency for a particular configuration of the third and fourth transmission lines and as a function of the electrical length of the third transmission line; and

FIG. 4C illustrates the impedance seen looking into the impedance matching stage at the second harmonic frequency in a Smith chart for a particular configuration of the third and fourth transmission lines and as a function of the electrical length of the third transmission line.

FIG. 1 illustrates a power amplifier 1 in accordance with the present invention that has an input 2 for receiving a signal to be amplified and an output 3 for outputting the amplified signal to a load ZL.

Power amplifier 1 comprises a power transistor 4, for example a GaN FET. Input 5 of power transistor 1 is connected to input 2, whereas output 6 of power transistor 1 is connected via a first auxiliary matching stage 20 to an input 11 of impedance matching stage 10. Output 12 of impedance matching stage 10 is connected via a second auxiliary matching stage 30 to a load having load impedance ZL.

Typically, power transistor 4 is a packaged device. The electrical connection between the intrinsic drain of power transistor 4 and input 11 of impedance matching stage 10 is assumed to be absorbed into first auxiliary impedance matching stage 20. For a lead frame-based package, first auxiliary impedance stage 20 for example includes bond wires extending from the drain of power transistor 4 to the output lead of the package, the parasitic output lead capacitance, the parasitic output lead inductance, transmission line or conductive track segments on the printed circuit board on which power transistor 4 is mounted, and optional shunt components, such as surface mounted devices. First auxiliary matching stage 20 may transform the relatively low output impedance of power transistor 4 to a higher value.

Impedance matching stage 10 comprises an open-circuited stub 13 that comprises a third transmission line TL3 that is characterized by a given characteristic impedance ZL3 and electrical length EL3, and a fourth transmission line TL4 that is characterized by a given characteristic impedance ZL4 and electrical length EL4.

Impedance matching stage 10 further comprises a series branch 15 that comprises a second transmission line TL2 that is characterized by a given characteristic impedance ZL2 and electrical length EL2. Transmission line TL2 extends between input 11 and output 12 of impedance matching stage 10.

Impedance matching stage 10 also comprises an open-circuited stub 14 that comprises a first transmission line TL1 that is characterized by a given characteristic impedance ZL1 and electrical length EL1.

Power amplifier 1 operates at a given fundamental frequency. This frequency may correspond to a carrier frequency of a telecommunications signal. For example, the fundamental frequency may lie in a range between 0.5 GHz and 40 GHz. Hereinafter, the fundamental frequency will be indicated using f0. The second harmonic frequency will be indicated using f2.

According to the present invention, EL1=90 degrees at f2. As a result, TL1 will act as a short at f2. However, at f0, TL1 will form a particular reactive impedance that is parallel to ZL. Similarly, according to the present invention EL2=90 degrees at f2. As a result, the RF short formed at f2 at output 12 is transformed by TL1 into an RF open at input 11. At f0, TL2 will transform the parallel combination of the reactive part of TL1 and ZL to a particular impedance seen looking into TL2 at f0. At f2, TL2 will transform the RF short at output 12 to an RF open at input 11.

Fourth transmission line TL4 is short-circuited. In FIG. 1, this is achieved by connecting an end of fourth transmission line TL4 to a decoupling capacitor Cdec. This capacitor has a large capacitance value to create a ground, at least for frequencies above 100 MHz, thereby forming an RF short. Furthermore, in FIG. 1, a voltage supply Vdd is connected to fourth transmission line TL4 for biasing power transistor 4.

As a convenient design approach, EL3+EL4 is taken to equal 90 degrees at f0 and therefore to equal 180 degrees at f2. When Z3=Z4, TL3 and TL4 jointly form an impedance inverter transforming the RF short at f0 to an RF open seen looking into TL3. Consequently, in this case, the input impedance of impedance matching stage 10 is not affected by short-circuited stub 13. At f2, no impedance transformation would take place. Consequently, the impedance seen looking into TL3 at f2 would correspond to an RF short in the case that Z3=Z4.

By deviating from Z3=Z4 it becomes possible to design for a different impedance at f2 seen looking to TL3. Given a particular power transistor 4 and first auxiliary stage 20, it is possible to determine a desired impedance Zdes1, Zdes2 to be presented at input 11 both at f0 and f2, respectively.

FIG. 2 illustrates another embodiment of a power amplifier in accordance with the present invention. Here, power amplifier 100 is embodied as a Doherty amplifier comprising a main power transistor 4A and a peak power transistor 4B. Each of these transistors is coupled to an impedance matching stage 10A, 10B similar to impedance matching stage 10 of FIG. 1. However, in FIG. 2, second auxiliary impedance matching stage 20 is omitted and is replaced by a transmission line TL5. The combination of this transmission line with MIA, TL3A, TL4A, TL2A, and TL1A has an electrical length of (2n+1)×90 degrees at or near the fundamental frequency between the output of main power transistor 4A and combining node C and acts as an impedance inverter, with n=0, 1, 2 . . . . Similarly, the combination of M1B, TL1B, TL2B, TL3B, and TL4B has an electrical length of n×180 degrees at or near the fundamental frequency.

During operation, main power transistor 4A is biased in class AB, and peak power transistor 4B in class C. Consequently, at low input power levels, only power transistor 4A is on. At high input power levels, both main power transistor 4A and peak power transistor 4B are on. Due to impedance inverter formed by transmission line TL5, the load seen by main power transistor 4A is higher when peak power transistor 4B is switched off. This load modulation allows power amplifier 100 to obtain high power added efficiencies under power back off while also achieving high efficiencies under high input power conditions.

The phase offset of transmission line TL6 is such that the signals amplified by main power transistor 4A and peak power transistor 4B are added in-phase at combining node C.

Main power transistor 4A and peak power transistor 4B may have equal power capabilities. For other non-symmetric Doherty amplifiers, peak power transistor 4B may have a higher power capability.

In FIG. 2, components are referred to using an “A” or “B” in the reference sign. This is to illustrate that although the function of the components referred to for the main and peak paths is similar, the component size or component value may be different. For example, peak power transistor 4B may require different impedance values at the fundamental and second harmonic frequencies. This will result in different component sizes/values for at least M1B, TL1B, TL2B, TL3B, and TL4B when compared to MIA, TL1A, TL2A, TL3A, and TL4A.

Furthermore, several different Doherty configurations are known in the art, such as a parallel Doherty amplifier and an inverted Doherty amplifier. The present invention can be applied to each of these known configurations.

In FIG. 2, voltage source Vdd1 and voltage source Vdd2 may be different. To avoid a DC path between these voltage sources, a DC blocking capacitor may be included to separate the main and peak paths of the Doherty amplifier.

In the embodiments shown in FIGS. 1 and 2, power transistor 4, 4A, 4B is typically provided as a packaged device that is mounted on a printed circuit board. However, these transistors could also be provided as bare semiconductor dies that are mounted on a printed circuit board. The various transmission lines described above are generally realized in the printed circuit board on which power transistor 4, 4A, 4B is mounted. The invention does however not exclude embodiments in which some or all of the components M1, TL1, TL2, TL3, TL4, TL5, and TL6 and their equivalents in FIG. 2 are realized on the same or a different semiconductor die as the power transistor. For example, some or all of these components can be realized on a passive die, such as a semiconductor die or ceramic die.

Furthermore, some or all of the components M1, TL1, TL2, TL3, TL4, TL5, TL6 and their equivalents in FIG. 2 can be replaced by an equivalent thereof, such as lumped element equivalents. For example, TL2, TL2A, and/or TL2B can be replaced by a L-C-L or C-L-C equivalent network.

In the above, the present invention has been explained using detailed embodiments thereof. The present invention is however not limited by these embodiments. Rather, various modifications are possible without deviating from the scope of the present invention that is defined by the appended claims and their equivalents.

1. An impedance matching stage comprising:
an input and an output;
a short-circuited stub connected to the input;
an open-circuited stub connected to the output; and
a series branch arranged in between the input and the output,
wherein the short-circuited stub comprises a third transmission line arranged in series with a shorted fourth transmission line, said third transmission line having a third characteristic impedance and a third electrical length, and said fourth transmission line having a fourth characteristic impedance and a fourth electrical length, wherein a sum of the third electrical length and the fourth electrical length equals 90 degrees at or near the fundamental frequency, and wherein the third characteristic impedance and the fourth characteristic impedance are different,
wherein an impedance at a fundamental frequency seen looking into the series branch when a load impedance is connected to the output substantially equals a first desired impedance,
wherein the short-circuited stub is configured to have an input impedance at a second harmonic frequency that substantially equals a second desired impedance,
wherein an impedance at the second harmonic frequency seen looking into the series branch with the load impedance connected to the output is substantially greater than the second desired impedance, and
wherein an input impedance of the short-circuited stub at the fundamental frequency is substantially greater than the first desired impedance.

2. The impedance matching stage according to claim 1, wherein the open-circuited stub comprises a first transmission line having a first characteristic impedance and a first electrical length, wherein the first electrical length corresponds to 45 degrees at or near the fundamental frequency, wherein the series branch comprises a second transmission line having a second characteristic impedance and a second electrical length, and wherein the second electrical length corresponds to 45 degrees at or near the fundamental frequency.

3. The impedance matching stage according to claim 2, wherein a voltage standing wave ratio associated with an impedance at the fundamental frequency at the input looking into the series branch and referenced to the first desired impedance is less than 1.3.

4. The impedance matching stage according to claim 2, wherein a voltage standing wave ratio associated with an input impedance of the short-circuited stub at the second harmonic frequency referenced to the second desired impedance is less than 2.

5. The impedance matching stage according to claim 2, wherein the first characteristic impedance and second characteristic impedance are different.

6. The impedance matching stage according to claim 2, wherein the first characteristic impedance and second characteristic impedance are such that, for a given load impedance connected at the output, the impedance looking into the series branch from the input substantially equals the first desired impedance at the fundamental frequency.

7. The impedance matching stage according to claim 1, wherein a ratio between the third characteristic impedance and fourth characteristic impedance lies in a range between 0.2<=R3<=5.

8. The impedance matching stage according to claim 1, further comprising a printed circuit board, wherein at least one of the short-circuited stub, the open-circuited stub, and the series branch is realized on or in the printed circuit board.

9. A power amplifier comprising:
a main input terminal for receiving a signal to be amplified;
a main output terminal for connecting to a load and for outputting the amplified signal to said load;
a power transistor having an input terminal electrically connected to the main input terminal, and an output terminal; and
the impedance matching stage according to claim 1, wherein the input of the impedance matching stage is electrically connected to the output terminal of the power transistor, and wherein the output of the impedance matching stage is connected to the main output terminal.

10. The power amplifier according to claim 9, wherein the power amplifier is a switched-mode power amplifier.

11. The power amplifier according to claim 10, wherein the switched-mode power amplifier is a class-F amplifier, a class-E amplifier, or a class-J amplifier.

12. The power amplifier according to claim 9, wherein the power amplifier is a Doherty amplifier.

13. The power amplifier according to claim 9, further comprising:
a first auxiliary impedance matching network arranged in between the output terminal of the power transistor and the input of the impedance matching stage; and/or
a second auxiliary impedance matching network arranged in between the output of the impedance matching stage and the main output terminal.

14. The power amplifier according to claim 9, wherein the power transistor comprises:
a silicon-based laterally diffused metal-oxide-semiconductor (LDMOS) transistor; or
a gallium nitride-based field-effect transistor (FET).

15. (canceled)

16. A power amplifier comprising:
a main input terminal for receiving a signal to be amplified;
a main output terminal for connecting to a load and for outputting the amplified signal to said load;
a power transistor having an input terminal electrically connected to the main input terminal, and an output terminal; and
the impedance matching stage according to claim 8, wherein the input of the impedance matching stage is electrically connected to the output terminal of the power transistor, wherein the output of the impedance matching stage is connected to the main output terminal, and wherein the power transistor is provided as a packaged device or bare semiconductor die mounted on the printed circuit board.
